(19) United States
(12) Patent Application Publication
(10) Pub. No.: US 2009/0312987 A1
(43) Pub. Date: Dec. 17, 2009

(54) Ambient Light Sensor and Electronic Equipment

(75) Inventors: Yoshitsugu Uedaira, Kyoto (JP); Junji Fujino, Kyoto (JP)

Correspondence Address: FISH & RICHARDSON P.C., P.O. BOX 1022, MINNEAPOLIS, MN, 55440-1022, US

(73) Assignee: Rohm Co., Ltd., Kyoto-shi, Kyoto (JP)

(21) Appl. No.: 12/300,226

(22) PCT Filed: May 17, 2007
(86) PCT No.: PCT/JP2007/060128

§ 371 Date: Mar. 31, 2009

(30) Foreign Application Priority Data
May 18, 2006 (JP) 2006-139239

(51) Int. Cl. G06F 15/00; H03F 3/08

(52) U.S. Cl. 702/189; 250/214 A

(57) ABSTRACT

An ambient light sensor (1) incorporated in electronic equipment includes a plurality of amplifiers (11, 12). Receiving signals (S1, S2) corresponding to the plurality of amplifiers (11, 12) respectively, the plurality of amplifiers (11, 12) vary an amplification factor. Depending on combination of the amplification factors (such as 10 and 1) of the plurality of amplifiers (11, 12), a current output from a photodiode (10) is amplified at any amplification factor, for example, of 1, 10, and 100. An appropriate amplification factor can thus be selected depending on a current output from the photodiode (10). In addition, a voltage (VOUT) output from the ambient light sensor (1) can be controlled such that it is within a widest input voltage range of an AD converter (21).

### TECHNICAL FIELD

The present invention relates to an ambient light sensor and electronic equipment, and particularly to an ambient light sensor capable of achieving a wider range of illuminance detection and electronic equipment including the ambient light sensor.

### BACKGROUND ART

An ambient light sensor is a sensor sensing ambient brightness such as “bright” and “dark”. For example, a display device incorporating an ambient light sensor can adjust a luminance of a screen to a level felt optimal by a person. In addition, the display device incorporating the ambient light sensor can turn on a light source at a location where a person feels dark or turn off the light source at a location where a person feels bright.

FIG. 8 is a diagram showing an exemplary circuit configuration including a conventional ambient light sensor.

Referring to FIG. 8, an ambient light sensor 101 outputs a current in accordance with an illuminance of received light from a terminal TA. A resistor R1 is connected between terminal TA and a ground node. The current output from ambient light sensor 101 is converted to a voltage VOUT through resistor R1.

An AD converter (ADC) 121 is connected to terminal TA. Receiving voltage VOUT, AD converter 121 outputs digital data. The digital data output from AD converter 121 is input to a not-shown control device (such as a microcomputer). The control device performs various types of processing (such as illumination control of a light source) based on the digital data.

Ambient light sensor 101 includes a photodiode 110, NPN transistors QA, QB, and PNP transistors QC, QD. Photodiode 110 has a cathode connected to a node NA (power supply node) and an anode connected to a node NB.

A collector and a base of NPN transistor QA and a base of NPN transistor QB are all connected to node NB. An emitter of NPN transistor QA and an emitter of NPN transistor QB are both connected to a ground node.

An emitter of PNP transistor QC and an emitter of PNP transistor QD are both connected to node NA. A base and a collector of PNP transistor QC and a collector of NPN transistor QB are all connected to a node NC. A collector of PNP transistor QD is connected to terminal TA.

NPN transistors QA, QB and PNP transistors QC, QD form a current mirror circuit. A ratio of emitter size between NPN transistors QA, QB is set to a certain ratio. In addition, a ratio of collector size of PNP transistors QC, QD is set to a certain ratio. Thus, a ratio of a current that flows from photodiode 110 to the collector of NPN transistor QA to a current output from terminal TA is constantly maintained at a prescribed ratio (such as 1:10).

For example, Japanese Patent Laying-Open No. 11-186971 (Patent Document 1) discloses a light receiver including a plurality of amplifiers different from each other in an amplification factor. The light receiver selects an amplifier having an optimal amplification factor from among the plurality of amplifiers, depending on intensity of incident light.

In addition, Japanese Patent Laying-Open No. 11-298259 (Patent Document 2) discloses a light reception device including two amplifiers different from each other in an amplification factor connected in parallel, and a selection circuit selecting, out of the two amplifiers, an amplifier not performing an operation in a saturation region.

### Patent Document 1: Japanese Patent Laying-Open No. 11-186971

### Patent Document 2: Japanese Patent Laying-Open No. 11-298259

### DISCLOSURE OF THE INVENTION

### Problems to be Solved by the Invention

Generally, in a light-receiving element such as a photodiode, magnitude of a current output from the light-receiving element is proportional to an illuminance of light received by the light-receiving element. For example, a current output by the light-receiving element when it receives light of illuminance of 100,000 lux is 100,000 times as great as the current output by the light-receiving element when it receives light of illuminance of 1 lux. Here, voltage VOUT varies, for example, in a range from several ten μV to several V.

A range in which a general AD converter is capable of analog data conversion (widest input voltage range), however, is narrower than the range of voltage VOUT described above. Therefore, a general AD converter cannot adapt to voltage VOUT having such a wide range.

On the other hand, the ambient light sensor is used, for example, for illumination control of an LED (Light Emitting Diode) backlight mounted on a liquid crystal display, illumination control of a keypad LED of a portable phone, or the like. For example, the illuminance of the LED backlight varies in a range from 0 to 100,000 [Lx] (“Lx” represents “lux”). Meanwhile, the illuminance of the keypad LED of the portable phone varies, for example, in a range from 0 to 100 [Lx].

As applications of the ambient light sensor are thus various, the range of illuminance that can be detected by the ambient light sensor is preferably as wide as possible. Japanese Patent Laying-Open No. 11-186971 (Patent Document 1), however, is silent about whether the light receiver can detect the illuminance over such a wide range or not. In addition, in the light receiver disclosed in Japanese Patent Laying-Open No. 11-186971 (Patent Document 1), as each amplifier is constantly operating, current consumption is great and a chip area is large. For these reasons, the light receiver described above is not suitable for use in electronic equipment such as a portable phone.

An object of the present invention is to provide an ambient light sensor capable of achieving a wider range of illuminance detection while achieving suppressed power consumption and reduced chip area, and electronic equipment including the ambient light sensor.

### Means for Solving the Problems

In summary, the present invention is directed to an ambient light sensor, including a light-receiving unit receiving light and outputting an electrical signal in accordance with an illuminance of the received light, and a plurality of amplifier units connected in series, for amplifying the electrical signal. At least one amplifier unit of the plurality of amplifier units varies an amplification factor in response to a control signal.

Preferably, at least one amplifier unit switches the amplification factor between 1 and a value greater than 1.

More preferably, the value greater than 1 is a value obtained by subtracting 1 from a power of 10.

Preferably, at least one amplifier unit is capable of switching the amplification factor between at least two values. At least one amplifier unit includes a noise reduction circuit that operates when the amplification factor is set to a smaller value out of the two values.

Preferably, at least one amplifier unit includes a first transistor having a collector electrically coupled to an input node receiving an input signal and an emitter electrically coupled to a constant potential node, a second transistor having a base electrically coupled to a base of the first transistor, an emitter electrically coupled to the constant potential node, and a collector electrically coupled to an output node, and a third transistor having a base electrically coupled to the base of the first transistor and a collector electrically coupled to the output node. A ratio of a current flowing through the second transistor to a current flowing through the first transistor is 1. A ratio of a current flowing through the third transistor to the current flowing through the first transistor is a value greater than 1. At least one amplifier unit further includes a switch electrically coupled between an emitter of the third transistor and the constant potential node, for switching between conduction and non-conduction in response to a corresponding control signal among a plurality of control signals.

More preferably, at least one amplifier unit further includes another switch provided between the emitter of the third transistor and the base of the third transistor. Another switch is non-conductive when the switch is conductive, and it is conductive when the switch is non-conductive.

Further preferably, at least one amplifier unit is the amplifier unit in a stage subsequent to the amplifier unit in a first stage out of the plurality of amplifier units. The ambient light sensor further includes another amplifier unit connected subsequent to the plurality of amplifier units and having a fixed amplification factor.

According to another aspect of the present invention, electronic equipment includes the ambient light sensor. The ambient light sensor includes a light-receiving unit receiving light and outputting an electrical signal in accordance with an illuminance of the received light, and a plurality of amplifier units connected in series, for amplifying the electrical signal. At least one amplifier unit of the plurality of amplifier units varies an amplification factor in response to a control signal.

Preferably, the electronic equipment further includes an AD converter converting an output voltage of the ambient light sensor to digital data, and a processing circuit outputting a plurality of control signals to the ambient light sensor, reading the digital data, and multiplying the read digital data by a coefficient. The processing circuit determines the coefficient in correspondence with the plurality of control signals that are output.

More preferably, the electronic equipment further includes a key input portion of which luminance can be varied, a display portion of which luminance can be varied, and a control device controlling the luminance of the key input portion and the display portion in accordance with a result of detection by the ambient light sensor.

### Effects of the Invention

According to the present invention, a wider illuminance detection range of the ambient light sensor can be achieved.

### BRIEF DESCRIPTION OF THE DRAWINGS

FIG. 1 is a schematic block diagram of electronic equipment including a photodetector according to the present embodiment.

FIG. 2 is a block diagram illustrating a configuration of an ambient light sensor 1 in FIG. 1.

FIG. 3 is a circuit diagram showing a specific configuration example of ambient light sensor 1 shown in FIG. 2.

FIG. 4 is a diagram showing relation between combination of setting of switches SW1, SW2 in FIG. 3 and an amplification factor (gain) of amplifiers 11 to 13 as a whole.

FIG. 5 is a diagram showing an exemplary range of illuminance that can be detected by ambient light sensor 1 according to the present embodiment.

FIG. 6 is a flowchart showing control processing performed by a processing circuit 22 shown in FIG. 2.

FIG. 7 is a diagram showing a specific example of the electronic equipment incorporating ambient light sensor 1 according to the present embodiment.

FIG. 8 is a diagram showing an exemplary circuit configuration including a conventional ambient light sensor.

FIG. 9 is a diagram showing a variation of an amplifier shown in FIG. 3.

### DESCRIPTION OF THE REFERENCE SIGNS

1, 101 ambient light sensor; 2 control device; 3 drive circuit; 4 light-emitting unit; 10, 110 photodiode; 11 to 13 amplifier; 21, 121 AD converter; 22 processing circuit; 30 key input portion; 32 display portion; 32A region; 40 microphone; 42 speaker; 50 start key; 52 end key; 60 numeric key; 100 electronic equipment (portable phone); N1 to N3, N5 to N9, NA, NB, NC node; Q1 to Q3, Q7, Q8, Q11, Q12, Q15, Q16, QA, QB NPN transistor; Q4 to Q6, Q9, Q10, Q13, Q14, Q17, Q18, QC, QD PNP transistor; QM1 to QM3 MOS transistor; R1 resistor; ST1 to ST20 step; SW1 to SW4 switch; T1 to T3, TA terminal.

### BEST MODES FOR CARRYING OUT THE INVENTION

An embodiment of the present invention will be described hereinafter in detail with reference to the drawings. In the drawings, the same or corresponding elements have the same reference characters allotted.

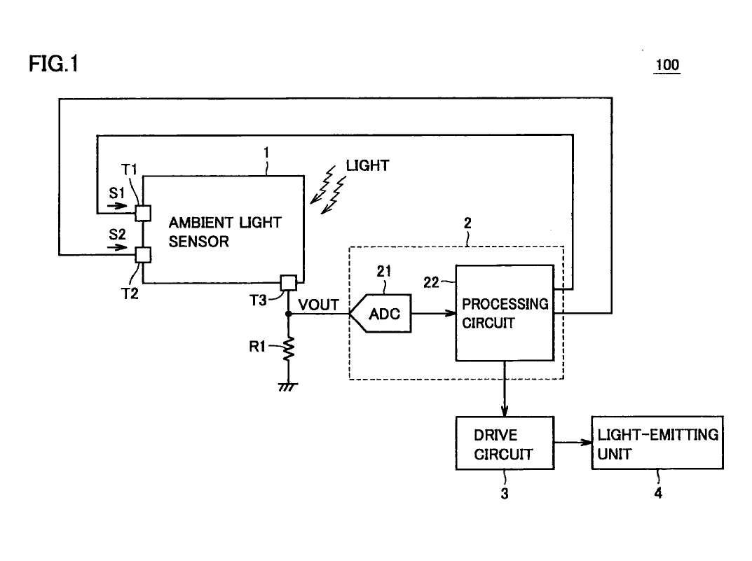

FIG. 1 is a schematic block diagram of electronic equipment including a photodetector according to the present embodiment.

Referring to FIG. 1, electronic equipment 100 includes an ambient light sensor 1, a control device 2, a drive circuit 3, and a light-emitting unit 4.

Ambient light sensor 1 has terminals T1 to T3. Receiving light, ambient light sensor 1 outputs from terminal T3, a current varying in magnitude in proportion to the illuminance of light. The current output from terminal T3 is converted to voltage VOUT through resistor R1. Signals S1 and S2 are input to terminals T1 and T2, respectively. Signals S1 and S2 are control signals varying the amplification factor in ambient light sensor 1.

Control device 2 includes an AD converter (ADC) 21 and a processing circuit 22. AD converter 21 converts voltage VOUT and outputs, for example, 8-bit digital data. A range in which AD converter 21 is capable of analog data conversion (widest input voltage range) is set, for example, to a range from 0.2V to 2V.

Processing circuit 22 reads the digital data from AD converter 21. Processing circuit 22 obtains information on the illuminance sensed by ambient light sensor 1 by multiplying the digital data by a certain coefficient. Processing circuit 22 controls drive circuit 3 in accordance with the obtained information on the illuminance.

In addition, processing circuit 22 sends signals S1 and S2 to ambient light sensor 1 based on the digital data received from AD converter 21, so as to control ambient light sensor 1 such that voltage VOUT is within the input voltage range of AD converter (ADC) 21. Moreover, processing circuit 22 determines a coefficient for multiplication described above, in correspondence with output signals S1 and S2.

The digital data output from AD converter 21 has a value always in a prescribed range, regardless of a level of illuminance. Processing circuit 22 can obtain correct information on the illuminance from the read digital data by determining the coefficient. Details of control of ambient light sensor 1 by processing circuit 22 will be described later.

Drive circuit 3 drives light-emitting unit 4 under the control of processing circuit 22. In an example where electronic equipment 100 is a liquid crystal display, light-emitting unit 4 is, for example, an LED backlight. Alternatively, in an example where electronic equipment 100 is a portable phone, light-emitting unit 4 is, for example, an LED backlight for display and/or an LED backlight for a keypad.

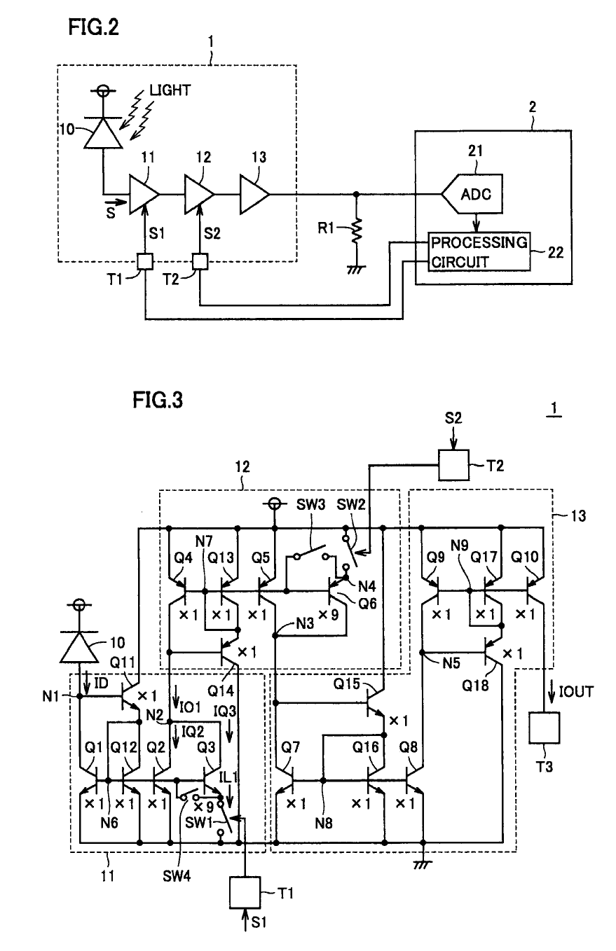

FIG. 2 is a block diagram illustrating a configuration of ambient light sensor 1 in FIG. 1.

Referring to FIG. 2, ambient light sensor 1 includes a photodiode 10 and amplifiers 11 to 13. Photodiode 10 and amplifiers 11 to 13 are integrated, for example, on a single semiconductor chip.

Photodiode 10 has a cathode connected to a power supply node and an anode connected to an input terminal of amplifier 11. Receiving light, photodiode 10 outputs an electrical signal S.

Amplifiers 11 to 13 are connected in series and amplify electrical signal S. Amplifiers 11 and 12 vary the amplification factors in response to signals S1 and S2 sent from processing circuit 22, respectively. Preferably, the amplification factor is switched between 1 and a value greater than 1. More preferably, the value greater than 1 is a power of 10.

For example, when ambient light sensor 1 receives light of high illuminance (such as sunlight), a large current flows through photodiode 10. Here, by setting the amplification factor of amplifiers 11 and 12 to 1, voltage VOUT can be within the input voltage range of AD converter 21.

The number of amplifiers varying the amplification factor in response to the control signal is not limited to two, so long as a plurality of amplifiers are provided. In addition, switching between the amplification factors of amplifiers 11 and 12 is not limited to switching between 1 and the value greater than 1. For example, the amplification factor of amplifiers 11 and 12 may be switched between 2 and 3. The description below, however, is given, assuming that the amplification factor of amplifiers 11 and 12 is switched between 1 and 10.

Amplifier 11 varies the amplification factor in response to signal S1 received through terminal T1. More specifically, for example, amplifier 11 sets the amplification factor to 10 when signal S1 is at H level, and it sets the amplification factor to 1 when signal S1 is at L level.

Amplifier 12 varies the amplification factor in response to signal S2 received through terminal T2. More specifically, for example, amplifier 12 sets the amplification factor to 10 when signal S2 is at H level, and it sets the amplification factor to 1 when signal S2 is at L level.

Amplifiers 11 and 12 thus vary the amplification factors upon receiving signals S1 and S2 corresponding to amplifiers 11 and 12, respectively. Depending on combination of the amplification factors (10 and 1) of amplifiers 11 and 12, the current output from photodiode 10 is amplified at any amplification factor of 1, 10 and 100. An appropriate amplification factor can thus be selected in accordance with the current output from photodiode 10. In addition, voltage VOUT can be controlled such that it is within a widest input voltage range of AD converter 21. Therefore, according to the present embodiment, a wider illuminance detection range of the ambient light sensor can be achieved.

Amplifier 13 is provided subsequent to amplifiers 11 and 12. The amplification factor of amplifier 13 is fixed, for example, to several times (such as two). Amplifiers 11 and 12 amplify the current output from photodiode 10 at any amplification factor of 1, 10 and 100. By connecting amplifier 13 to amplifiers 11 and 12, fine control such that voltage VOUT is within the input voltage range of AD converter 21 can be achieved. For the sake of convenience of illustration, the amplification factor of amplifier 13 is assumed as 1 in the description below.

Here, as another method of setting voltage VOUT within the widest input voltage range of AD converter 21, for example, a method of varying a resistance value of resistor RI while fixing the amplification factor of amplifiers 11 and 12 (a method of lowering a resistance value of resistor RI as the current output from ambient light sensor 1 is greater) is available. According to this method, however, as the illuminance of light received by photodiode 10 is higher, the current output from the ambient light sensor becomes greater, and therefore, power consumption in resistor R1 increases. Namely, the ambient light sensor causes increase in power consumption of the electronic equipment.

In addition, in varying the resistance value of resistor R1, as the illuminance is lower, the resistance value of resistor R1 should be set higher. As the resistance value of resistor R1 is higher, a time constant of voltage VOUT becomes greater, and therefore, response of control device 2 is also delayed. As the resistance value of resistor R1 is further raised, noise included in voltage VOUT may increase or the number of parts externally attached to ambient light sensor 1 (such as a transistor) may increase.

In the present embodiment, the amplification factor of the plurality of amplifiers included in ambient light sensor 1 is varied. By doing so, the resistance value of resistor R1 may remain fixed. Therefore, according to the present embodiment, these problems can be solved.

In addition, as shown in FIG. 2, in the present embodiment, the plurality of amplifiers are connected in series so that the circuit size can be made smaller. In order to detect light of low illuminance, ambient light sensor 1 should include an amplification factor having a high amplification factor (such as an amplifier having an amplification factor of 1000). For example, if three amplifiers having amplification factors of 10, 100 and 1000 respectively are mounted on a semiconductor chip as in the light receiver disclosed in Japanese Patent Laying-Open No. 11-186971 (Patent Document 1), an area of the semiconductor chip becomes inevitably large.

According to the present embodiment, the plurality of amplifiers having amplification factors of powers of 10 are connected in series, so that light of low illuminance can readily be detected (in other words, a higher amplification factor is set) while suppressing increase in the circuit area.

FIG. 3 is a circuit diagram showing a specific configuration example of ambient light sensor 1 shown in FIG. 2.

Referring to FIGS. 3 and 2, amplifier 11 includes NPN transistors Q1 to Q3, Q11, and Q12, and switches SW1 and SW4.

NPN transistor Q1 has a collector connected to a node N1, a base connected to a node N6, and an emitter connected to a ground node (that is, a constant potential node). NPN transistor Q2 has a base connected to node N6 (that is, the base of NPN transistor Q1), an emitter connected to the ground node, and a collector connected to a node N2. NPN transistor Q3 has a base connected to node N6, and a collector connected to node N2. Switch SW1 is connected between an emitter of NPN transistor Q3 and the ground node. NPN transistors Q1 to Q3 correspond to first to third transistors in the present invention, respectively.

Switch SW4 is connected between the base of NPN transistor Q3 and the emitter of NPN transistor Q3.

NPN transistor Q11 has a collector connected to the power supply node, a base connected to node N1, and an emitter connected to node N6. NPN transistor Q12 has a collector and a base connected to node N6 and an emitter connected to the ground node.

The signs such as “X1” provided to NPN transistors Q1 to Q3, Q11, and Q12 indicate a ratio of the current that flows through each of NPN transistors Q1 to Q3, Q11, and Q12 to the current that flows through NPN transistor Q1. For example, the ratio of the current that flows between the collector and the emitter of NPN transistor Q2 to the current that flows between the collector and the emitter of NPN transistor Q1 is 1. The ratio of the current that flows between the collector and the emitter of NPN transistor Q3 to the current that flows between the collector and the emitter of NPN transistor Q1 is 9 (=10−1).

Switch SW1 switches between conduction and non-conduction in response to signal S1 input to terminal T1. When signal S1 is at H level, switch SW1 is conductive, and when signal S1 is at L level, switch SW1 is non-conductive.

Switch SW4 operates in coordination with switch SW1. When switch SW1 is conductive, switch SW4 is non-conductive. When switch SW1 is non-conductive, switch SW4 is conductive. The noise of a current IOUT can thus be lowered.

NPN transistors Q1 to Q3, Q11, and Q12 form a current mirror circuit. When switch SW1 is non-conductive, a mirror ratio of the current mirror is 1. When switch SW1 is conductive, the mirror ratio of the current mirror is 10.

Amplifier 12 includes PNP transistors Q4 to Q6, Q13, and Q14, and switches SW2 and SW3.

PNP transistor Q4 has a collector connected to node N2, a base connected to a node N7, and an emitter connected to the power supply node (that is, the constant potential node). PNP transistor Q5 has a base connected to node N7 (that is, the base of PNP transistor Q4), an emitter connected to the power supply node, and a collector connected to a node N3. PNP transistor Q6 has a base connected to node N7 and a collector connected to node N3. PNP transistors Q4 to Q6 correspond to the first to third transistors in the present invention, respectively.

Switch SW2 is connected between an emitter of PNP transistor Q6 and the power supply node. Switch SW3 is connected between the emitter of PNP transistor Q6 and the base of PNP transistor Q6.

PNP transistor Q13 has an emitter connected to the power supply node and a collector and a base connected to node N7. PNP transistor Q14 has an emitter connected to node N7, a base connected to node N2, and a collector connected to the ground node.

The signs such as “X1” provided to PNP transistors Q4 to Q6, Q13, and Q14 indicate a ratio of the current that flows through each of PNP transistors Q4 to Q6 to the current that flows through PNP transistor Q4. For example, the ratio of the current that flows between the emitter and the collector of PNP transistor Q5 to the current that flows between the emitter and the collector of PNP transistor Q4 is 1. The ratio of the current that flows between the emitter and the collector of PNP transistor Q6 to the current that flows between the emitter and the collector of PNP transistor Q4 is 9 (=10−1).

Switch SW2 switches between conduction and non-conduction in response to signal S2 input to terminal T2. When signal S2 is at H level, switch SW2 is conductive, and when signal S2 is at L level, switch SW2 is non-conductive.

Switch SW3 operates in coordination with switch SW2. When switch SW2 is conductive, switch SW3 is non-conductive. When switch SW2 is non-conductive, switch SW3 is conductive.

PNP transistors Q4 to Q6, Q13, and Q14 form a current mirror circuit. When switch SW2 is non-conductive (and when switch SW3 is conductive), a mirror ratio of the current mirror is 1. When switch SW2 is conductive (and when switch SW3 is non-conductive), the mirror ratio of the current mirror is 10.

Switch SW3 is provided in order to lower noise of current IOUT. Switches SW1 to SW4 are configured, for example, to include a transistor.

The reason why noise of current IOUT can be lowered by providing switch SW4 in amplifier unit 11 will be described hereinafter.

When switch SW1 is non-conductive, a leakage current IL1 flows through switch SW1. The total of currents that flow into the collectors of NPN transistors Q2 and Q3 is assumed as IO1. Assuming the currents that flow into the collectors of NPN transistors Q2 and Q3 as IQ2 and IQ3 respectively, IO1 is expressed in the following Equation (1).

IO1=IQ2+IQ3 (1)

Here, if switch SW4 is not provided, IQ3=IL1. Therefore, modifying Equation (1), current IO1 is expressed in the following Equation (2).

IO1=IQ2+IL1 (2)

Here, assuming a degree of current amplification of NPN transistor Q3 (collector current/base current) as hFE_Q3, the base current of NPN transistor Q3 is as expressed in the following Equation (3).

IL1/hFE_Q3 (3)

On the other hand, as the mirror ratio of the current mirror formed by NPN transistors Q1 and Q2 is 1, magnitude of current IQ2 is equal to magnitude of the collector current of NPN transistor Q1, that is, magnitude obtained by subtracting the base current of NPN transistor Q11 from a current ID. On the other hand, the collector current of NPN transistor Q11 ultimately turns out to be the base current of NPN transistor Q3. Assuming the degree of current amplification of NPN transistor Q11 as hFE_Q11, the base current of NPN transistor Q11 is as shown in the following Equation (4).

(IL1/hFE_Q3)/hFE_Q11 (4)

Therefore, current IQ2 is as shown in the following Equation (5).

IQ2=ID−(IL1/hFE_{—}Q3)/hFE_{—}Q11 (5)

From Equations (2) and (5), current IO1 is as shown in the following Equation (6).

IO1={ID−(IL1/hFE_{—}Q3)/hFE_{—}Q11}+IL1 (6)

As the degrees of current amplification hFE_Q3 and hFE_Q11 are both high (for example, 100), IO is substantially equal to ID+IL1 as seen in Equation (6). If switch SW4 is not provided, current IL1 is amplified by amplifier unit 12, which may result in great noise in current IOUT.

On the other hand, if switch SW4 is provided, current IQ3=0, and relation of IO1=IQ2 is satisfied based on Equation (1). In addition, based on Equation (4), the base current of NPN transistor Q11 is (IL1/hFE_Q11). Therefore, here, current IO1 is as shown in the following Equation (7).

IO1=ID−(IL1/hFE_{—}Q11) (7)

Here, current IL1 is multiplied by 1/hFE_Q11. Therefore, influence on current IO1 by the leakage current can be lowered. The noise in current IOUT can thus be lowered.

The reason why noise in current IOUT can be lowered by providing switch SW3 in amplifier unit 12 is the same as described above. The leakage current that flows through switch SW2 corresponds to leakage current IL1 described above. The current that flows between the emitter and the collector of PNP transistor Q5 corresponds to current IQ2 described above. The current that flows between the emitter and the collector of PNP transistor Q6 corresponds to current IQ3 described above. The base current of PNP transistor Q14 corresponds to the base current of NPN transistor Q11 described above.

Switches SW3 and SW4 correspond to the “noise reduction circuit” in the present invention. Each of amplifier units 11 and 12 can switch the amplification factor between at least two values (1 and 10). Switches SW3 and SW4 are conductive (operate) in order to eliminate noise from current IOUT when the amplification factor is set to a smaller value (that is, 1) out of the two values. It is noted that the “noise reduction circuit” is not limited to the switch, and a different component may be employed.

As shown in FIG. 3, basically, both of preceding and subsequent amplifiers (amplifiers 11 and 12) include the “noise reduction circuit.” An effect of removal of noise from current IOUT can thus be further higher. In order to make the area of the semiconductor chip smaller, however, the “noise reduction circuit” in any one of the preceding and subsequent amplifiers may not be provided. In such a case, the “noise reduction circuit” in the preceding amplifier is preferably removed. In an example where current ID is amplified by amplifier 1, the leakage current of switch SW2 increases accordingly. By providing the noise reduction circuit in amplifier 12 which is the subsequent amplifier, superposition of large noise on current IOUT can be prevented.

Amplifier 13 includes NPN transistors Q7, Q8, Q15, and Q16, and PNP transistors Q9, Q10, Q17, and Q18.

NPN transistor Q7 has a collector connected to node N3. A base of NPN transistor Q7 and a base of NPN transistor Q8 are both connected to a node N8. NPN transistor Q8 has a collector connected to a node N5. An emitter of NPN transistor Q7 and an emitter of NPN transistor Q8 are both connected to the ground node.

An emitter of PNP transistor Q9 and an emitter of PNP transistor Q10 are both connected to the power supply node. A base of PNP transistor Q9 and a base of PNP transistor Q10 are both connected to a node N9. PNP transistor Q9 has a collector connected to node NS. PNP transistor Q10 has a collector connected to terminal T3.

NPN transistor Q15 has a collector connected to the power supply node, a base connected to node N3, and an emitter connected to node N8.

NPN transistor Q16 has a collector and a base connected to node N8, and an emitter connected to the ground node.

PNP transistor Q17 has an emitter connected to the power supply node. PNP transistor Q15 has a base and a collector connected to node N9. PNP transistor Q18 has an emitter connected to node N9, a base connected to node N5, and a collector connected to node N9.

NPN transistors Q7, Q8, Q15, and Q16 and PNP transistors Q9, Q10, Q17, and Q18 form a current mirror circuit. A current that flows between the collector and the emitter of NPN transistor Q7 is equal to a current that flows between the collector and the emitter of NPN transistor Q8 (“X1”). In addition, a current that flows between the emitter and the collector of PNP transistor Q9 is equal to a current that flows between the emitter and the collector of PNP transistor Q10 (“X1”). Namely, the mirror ratio of this current mirror is 1.

It is noted that node N1 corresponds to an input terminal of amplifier 11. Node N2 corresponds to an output terminal of amplifier 11 and an input terminal of amplifier 12. Node N3 corresponds to an output terminal of amplifier 12 and an input terminal of amplifier 13. In addition, current ID output from photodiode 10 varies in accordance with light received by photodiode 10. Variation in current ID corresponds to electrical signal S in FIG. 2.

In addition, a ratio of the current that flows between the collector and the emitter of NPN transistor Q3 to the current that flows between the collector and the emitter of NPN transistor Q1 is not limited to 9, so long as any value obtained by subtracting 1 from a power of 10 is employed. For example, 99 (100−1) maybe employed. Similarly, a ratio of the current that flows between the emitter and the collector of PNP transistor Q6 to the current that flows between the emitter and the collector of PNP transistor Q4 is not limited to 9, so long as any value obtained by subtracting 1 from a power of 10 is employed.

In addition, the amplification factor of amplifier units 11 and 12 may be switched, for example, among three values (1, 10 and 100). Here, amplifier units 11 and 12 may permit switches SW4 and SW3 to be conductive respectively, for example, when the amplification factor is switched from 100 to 10.

FIG. 9 shows a variation of the amplifier shown in FIG. 3. Referring to FIGS. 9 and 3, an amplifier 11A is different from amplifier 11 in further including MOS transistors QM1 to QM3. Two electrodes of MOS transistor QM1 are connected to the emitter of NPN transistor Q1 and the ground node, respectively. Similarly, two electrodes of MOS transistor QM2 are connected to the emitter of NPN transistor Q12 and the ground node, respectively. Two electrodes of MOS transistor QM3 are connected to the emitter of NPN transistor Q2 and the ground node, respectively.

Each of MOS transistors QM1 to QM3 is maintained in the ON state by a signal input to the gate thereof. Switch SW1 is implemented by an MOS transistor, and an ON resistance of each of MOS transistors QM1 to QM3 is designed to be equal to an ON resistance of switch SW1.

In the case of amplifier 11 shown in FIG. 3, as the ON resistance of switch SW1 affects amplification of NPN transistor Q3 (lowers the amplification factor of NPN transistor Q3), the amplification factor of amplifier 11 may not precisely be set to 10. As shown in FIG. 9, however, by arranging the MOS transistor on the emitter side of each of NPN transistors Q1, Q12 and Q2, a resistance component of the same magnitude is produced on the emitter side of each of NPN transistors Q1 to Q3 and Q12. Amplifier 11A can thus amplify a signal with a target amplification factor.

In addition, NPN transistor Q3 is configured by connecting nine transistors as large as NPN transistor Q1 in parallel. As nine transistors included in NPN transistor Q3 and transistors Q1, Q12 and Q2 are formed under the same manufacturing conditions, the amplification factor of each of the nine transistors is the same as that of transistor Q1 (and transistors Q12 and Q2). Thus, error in manufacturing ambient light sensor I similarly affects all transistors. Therefore, according to the configuration shown in FIG. 9, as compared with an example where NPN transistor Q3 is configured with a single transistor having an amplification factor of 9, the amplification factor of amplifier 11A can more accurately be set to a target value.

Though not shown in FIG. 9, in amplifier 12 as well, an MOS transistor is connected between the emitter of each of PNP transistors Q4, Q15, Q5 and the power supply node as in amplifier 11A, and the MOS transistor is constantly in the ON state. In addition, PNP transistor Q6 is configured by connecting nine transistors as large as PNP transistor Q4 in parallel. As nine transistors included in PNP transistor Q6 and PNP transistors Q4, Q15 and Q5 are formed under the same manufacturing conditions, the amplification factor of each of the nine transistors is the same as that of PNP transistor Q4 (and PNP transistors Q15 and Q5).

In the ambient light sensor according to the present embodiment, a plurality of amplifiers each capable of switching between the amplification factors by means of the switch are connected in series. Accordingly, the ambient light sensor according to the present embodiment is more advantageous than the ambient light sensor configured by individually providing a plurality of amplifiers different from each other in amplification factor (for example, 2, 20 and 200) in that the circuit area can be made smaller and power consumption can be reduced. If the amplification factor is not accurate because of presence of a switch, however, error contained in a result of detection by the ambient light sensor may be great. According to the configuration shown in FIG. 9, the amplifier includes the noise reduction circuit and the MOS transistor for accurately adjusting the amplification factor. In addition, the transistor (NPN transistor Q3, PNP transistor Q6) in the amplifier having a large amplification factor is configured by connecting in parallel a plurality of transistors as large as the transistor small in amplification factor (NPN transistor Q1, PNP transistor Q4), that are formed under the same manufacturing conditions as that transistor. The amplification factor can thus be accurate.

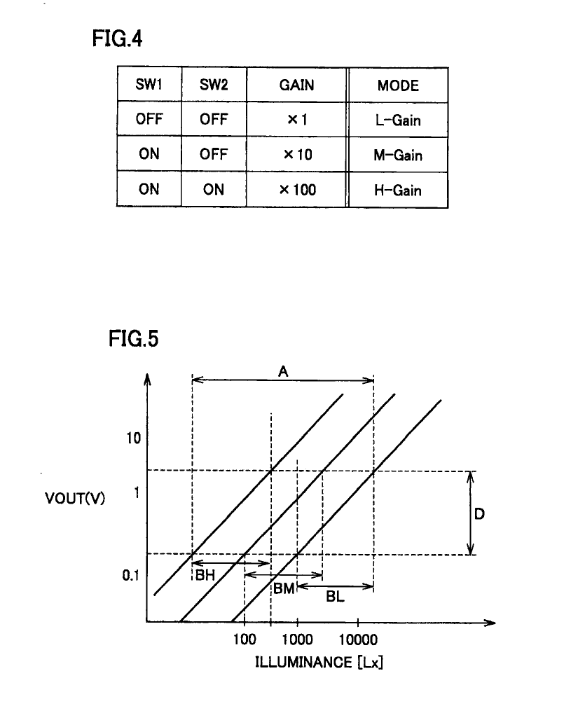

FIG. 4 is a diagram showing relation between combination of setting of switches SW1, SW2 in FIG. 3 and an amplification factor (gain) of amplifiers 11 to 13 as a whole.

Referring to FIGS. 4 and 3, initially, when switches SW1 and SW2 are both turned OFF (non-conductive), the gain is 1. Then, when switch SW1 is turned ON (conductive) and switch SW2 is turned OFF, the gain is 10. In addition, when switches SW1 and SW2 are both turned ON, the gain is 100. “L-Gain mode”, “M-Gain mode” and “H-Gain mode” shown in FIG. 4 indicate operation modes of the ambient light sensor in respective cases that the gains are set to 1, 10 and 100.

FIG. 5 is a diagram showing an exemplary range of illuminance that can be detected by ambient light sensor 1 according to the present embodiment.

Referring to FIG. 5, the abscissa of the graph represents an illuminance of light and the ordinate of the graph represents voltage VOUT. A range D of voltage VOUT represents the widest input voltage range of AD converter 21. Range D is, for example, a range from 0.2 to 2.

Description will be given hereinafter with reference to FIGS. 5 and 4. Ranges BL, BM, and BH represent ranges of illuminance that can be detected by ambient light sensor 1 in the L-Gain mode, the M-Gain mode, and the H-Gain mode, respectively.

A range A represents a range of illuminance that can be detected by ambient light sensor 1 according to the present embodiment. As shown in FIG. 5, range A is the total range obtained by superimposing ranges BL, BM and BH. For example, range A covers a range from several ten [Lx] to several ten thousand [Lx]. Thus, according to the present embodiment, a wider range of illuminance detection can be achieved.

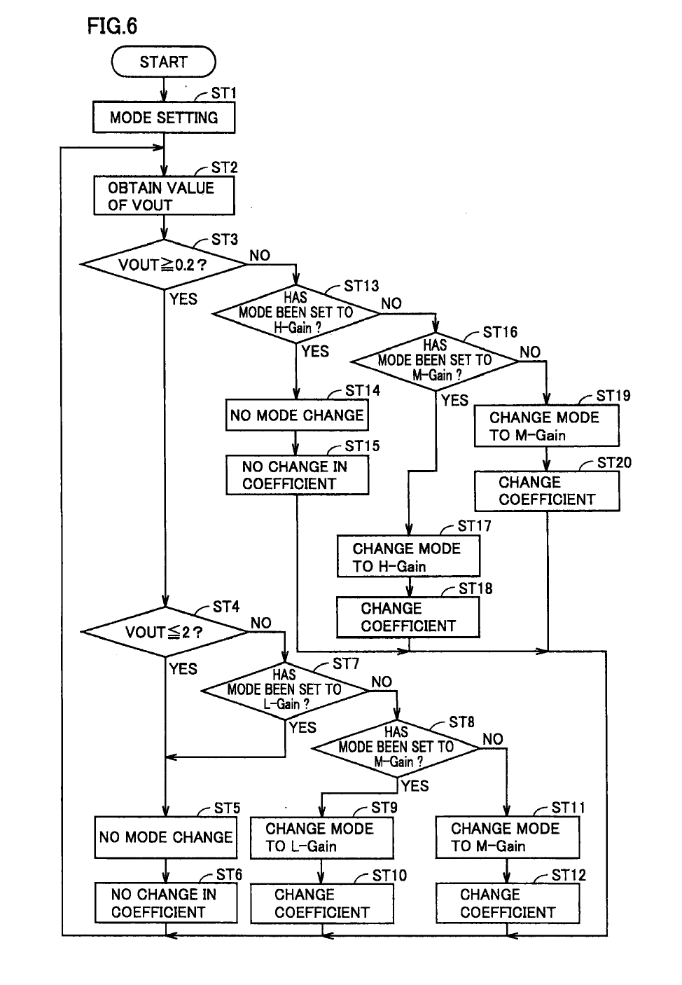

FIG. 6 is a flowchart showing control processing performed by processing circuit 22 shown in FIG. 2.

Referring to FIGS. 6 and 2, when the processing is started, initially in step ST1, processing circuit 22 carries out initial setting of the operation mode. The operation mode of ambient light sensor 1 here is set, for example, to the M-Gain mode. In addition, processing circuit 22 sets an initial value for the coefficient, in order to perform processing for multiplying the digital data received from AD converter 21 by the coefficient.

Then, in step ST2, processing circuit 22 obtains a value of voltage VOUT (digital data) from AD converter 21. Successively in step ST3, processing circuit 22 determines whether the value of voltage VOUT is equal to or greater than 0.2. Here, the lower limit value of the input voltage range of AD converter 21 (range in which analog data can be converted) is 0.2. When the value of voltage VOUT is equal to or greater than 0.2 (YES in step ST3), the process proceeds to step ST4. On the other hand, when the value of voltage VOUT is smaller than 0.2 (NO in step ST3), the process proceeds to step ST13 which will be described later.

In step ST4, processing circuit 22 determines whether the value of voltage VOUT is equal to or smaller than 2. Here, the upper limit value of the input voltage range of AD converter 21 is 2. When the value of voltage VOUT is equal to or smaller than 2 in step ST4 (YES in step ST4), the process proceeds to step ST5. On the other hand, when the value of voltage VOUT is greater than 2 (NO in step ST4), the process proceeds to step ST7.

When the value of voltage VOUT is within the input voltage range of AD converter 21, that is, when the value of voltage VOUT is within a range from 0.2 to 2, the process proceeds to step ST5. In step ST5, processing circuit 22 maintains the operation mode without change. Then, in step ST6, processing circuit 22 maintains the coefficient that has been set in advance without change. After the processing in step ST6 ends, the process returns to step ST2.

In step ST7, processing circuit 22 determines whether the current operation mode of ambient light sensor 1 has been set to the L-Gain mode or not. If the current operation mode has been set to L-Gain (YES in step ST7), the process proceeds to step ST5.

If the operation mode has been set to the L-Gain mode, the gain of ambient light sensor 1 has been set to a minimum value (1). Therefore, even though voltage VOUT is higher than 2V, processing circuit 22 cannot lower the gain of ambient light sensor 1. Accordingly, in step ST5, processing circuit 22 maintains the operation mode of ambient light sensor 1 in the L-Gain mode without change. In addition, in step ST6, processing circuit 22 maintains the coefficient without change.

If the operation mode has been set to the M-Gain mode or the H-Gain mode in step ST7 (NO in step ST7), the process proceeds to step ST8.

In step ST8, processing circuit 22 determines whether the current operation mode of ambient light sensor 1 has been set to the M-Gain mode or not. If the current operation mode has been set to the M-Gain mode (YES in step ST8), processing circuit 22 changes the operation mode of ambient light sensor 1 to the L-Gain mode in step ST9, in order to lower the gain of ambient light sensor 1. In addition, in step ST10, processing circuit 22 changes the coefficient.

On the other hand, if the current operation mode has been set to the H-Gain mode (NO in step ST8), processing circuit 22 changes the operation mode of ambient light sensor 1 to the M-Gain mode in step ST11, in order to lower the gain of ambient light sensor 1. In addition, in step ST12, processing circuit 22 changes the coefficient.

After the processing in step ST10 or step ST12 ends, the process returns to step ST2.

In step ST13, processing circuit 22 determines whether the current operation mode of ambient light sensor 1 has been set to the H-Gain mode or not. The case that the operation mode of ambient light sensor 1 has been set to the H-Gain mode means that the gain of ambient light sensor 1 has been set to a maximum value (100). If the operation mode of ambient light sensor 1 has been set to the H-Gain mode (YES in step ST13), the process proceeds to step ST14.

The case that the process proceeds to step ST14 means the case that processing circuit 22 can no longer raise the gain of ambient light sensor 1. Therefore, in step ST14, processing circuit 22 maintains the current operation mode of ambient light sensor 1 in the H-Gain mode without change. In addition, in step ST15, processing circuit 22 maintains the coefficient without change.

On the other hand, if the operation mode of ambient light sensor 1 has been set to the L-Gain mode or the M-Gain mode in step ST13 (NO in step ST13), the process proceeds to step ST16.

In step ST16, processing circuit 22 determines whether the current operation mode of ambient light sensor 1 has been set to the M-Gain mode or not. If the operation mode has been set to the M-Gain mode (YES in step ST16), processing circuit 22 changes the operation mode of ambient light sensor 1 to the H-Gain mode in step ST17, in order to raise the gain of ambient light sensor 1. In addition, instep ST18, processing circuit 22 changes the coefficient.

On the other hand, if the operation mode of ambient light sensor 1 has been set to the L-Gain mode in step ST16 (NO in step ST16), processing circuit 22 changes the operation mode of ambient light sensor 1 to the M-Gain mode in step ST19, in order to raise the gain of ambient light sensor 1. In addition, in step ST20, processing circuit 22 changes the coefficient.

After any of the processing in step ST15, the processing in step ST18, and the processing in step ST20 ends, the process returns to step ST2.

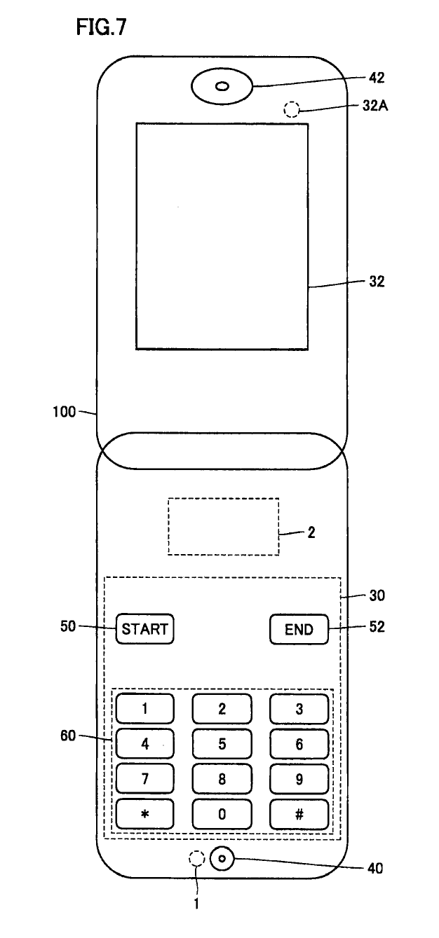

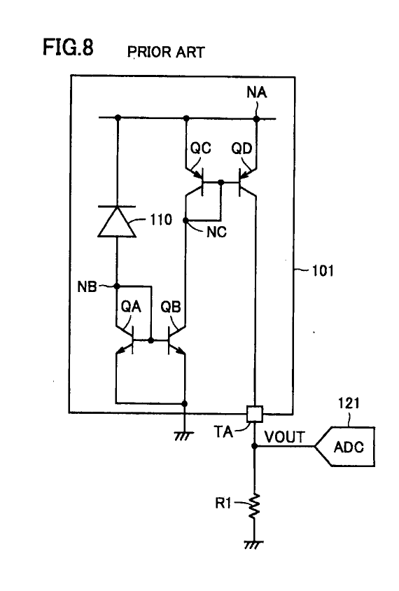

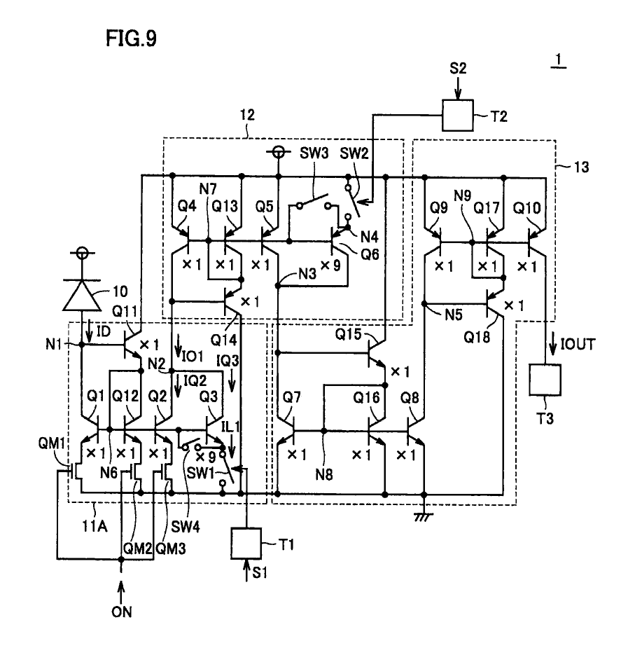

FIG. 7 is a diagram showing a specific example of electronic equipment incorporating ambient light sensor 1 according to the present embodiment.

Referring to FIG. 7, electronic equipment 100 is a portable phone. Electronic equipment 100 is hereinafter also referred to as “portable phone 100.”

Portable phone 100 includes a key input portion 30 and a display portion 32. Key input portion 30 accepts key input by a user. Luminance of key input portion 30 can be varied. Display portion 32 includes, for example, a liquid crystal display, a backlight, and a drive circuit for the backlight, and luminance thereof can be varied.

Key input portion 30 includes a start key 50, an end key 52, and a numeric key 60. Start key 50 accepts an input indicating start of a call or transmission. End key 52 accepts an input indicating end of a call or transmission. Numeric key 60 accepts an input of a number and a sign including “0” to “9”, “*”, and “#”. Key input portion 30 further includes a backlight and a drive circuit for the backlight (none of which is shown).

Portable phone 100 further includes a microphone 40 and a speaker 42. Microphone 40 accepts an input of voice and sound from the user and converts the same to a signal. Speaker 42 output voice and sound.

Portable phone 100 contains ambient light sensor 1. Ambient light sensor 1 may be provided adjacent to microphone 40, or may be provided in a region 32A (a region adjacent to display portion 32). A window for the ambient light sensor to receive light is provided at a position corresponding to ambient light sensor 1 in a housing of portable phone 100.

In portable phone 100, ambient light sensor 1 is specifically used in the following applications. Where a quantity of light emitted to ambient light sensor 1 is great, for example, during daytime or in a bright indoor space, control device 2 turns off the backlight of key input portion 30 and maximizes the luminance of the backlight of display portion 32. In contrast, where a quantity of light is small, for example, outdoors during the night, control device 2 turns on the backlight of key input portion 30 and decreases the quantity of light of the backlight of display portion 32 in accordance with the result of detection by ambient light sensor 1.

In an example where a part of a diffusion plate of the backlight is of a type reflecting light, control device 2 turns off the backlight when the illuminance detected by ambient light sensor 1 is high. Power consumption of a battery can thus be decreased.

As described above, the ambient light sensor according to the present embodiment includes a plurality of amplifiers varying the amplification factor in response to a plurality of externally input control signals. Therefore, according to the present embodiment, as the optimal amplification factor can be selected in accordance with the illuminance of light received by the photodiode, a wider range of illuminance detection can be achieved.

The light-receiving unit in the present invention is not limited to the photodiode, and it may be implemented by a phototransistor. In addition, though switches SW1 and SW2 shown in FIG. 3 are provided on the emitter side of the transistor, they may be provided on the collector side of the transistor. Moreover, though the number of stages of the amplifier units connected in series is set to three in FIGS. 2 and 3, the number of stages may be set to four or more, so that the size of the semiconductor chip may further be made smaller than in the example where a plurality of amplifier units are connected in parallel. Alternatively, the number of stages of the amplifier units connected in series may be set to two.

It should be understood that the embodiments disclosed herein are illustrative and non-restrictive in every respect. The scope of the present invention is defined by the terms of the claims, rather than the description above, and is intended to include any modifications within the scope and meaning equivalent to the terms of the claims.

1. An ambient light sensor, comprising:
a light-receiving unit receiving light and outputting an electrical signal in accordance with an illuminance of the received light; and
a plurality of amplifier units connected in series, for amplifying said electrical signal,
at least one amplifier unit of said plurality of amplifier units varying an amplification factor in response to a control signal.

2. The ambient light sensor according to claim 1, wherein
said at least one amplifier unit switches said amplification factor between 1 and a value greater than 1.

3. The ambient light sensor according to claim 2, wherein
said value greater than 1 is a value obtained by subtracting 1 from a power of 10.

4. The ambient light sensor according to claim 1, wherein
said at least one amplifier unit is capable of switching said amplification factor between at least two values and includes a noise reduction circuit that operates when said amplification factor is set to a smaller value out of said two values.

5. The ambient light sensor according to claim 1, wherein
said at least one amplifier unit includes
a first transistor having a collector electrically coupled to an input node receiving an input signal and an emitter electrically coupled to a constant potential node,
a second transistor having a base electrically coupled to a base of said first transistor, an emitter electrically coupled to said constant potential node, and a collector electrically coupled to an output node, and
a third transistor having a base electrically coupled to the base of said first transistor and a collector electrically coupled to said output node,
a ratio of a current flowing through said second transistor to a current flowing through said first transistor is 1,
a ratio of a current flowing through said third transistor to the current flowing through said first transistor is a value greater than 1, and
said at least one amplifier unit further includes a switch electrically coupled between an emitter of said third transistor and said constant potential node, for switching between conduction and non-conduction in response to a corresponding control signal among a plurality of said control signals.

6. The ambient light sensor according to claim 5, wherein
said at least one amplifier unit further includes another switch provided between the emitter of said third transistor and the base of said third transistor, and
said another switch is non-conductive when said switch is conductive and it is conductive when said switch is non-conductive.

7. The ambient light sensor according to claim 6, wherein
said at least one amplifier unit is the amplifier unit in a stage subsequent to the amplifier unit in a first stage out of said plurality of amplifier units, and
said ambient light sensor further comprises another amplifier unit connected subsequent to said plurality of amplifier units and having a fixed amplification factor.

8. Electronic equipment, comprising the ambient light sensor according to any one of claims 1 to 7.

9. The electronic equipment according to claim 8, further comprising:
an AD converter converting an output voltage of said ambient light sensor to digital data; and
a processing circuit outputting a plurality of said control signals to said ambient light sensor, reading said digital data, and multiplying read said digital data by a coefficient, wherein
said processing circuit determines said coefficient in correspondence with output said plurality of control signals.

10. The electronic equipment according to claim 8, further comprising:
a key input portion of which luminance can be varied;
a display portion of which luminance can be varied; and
a control device controlling the luminance of said key input portion and said display portion in accordance with a result of detection by said ambient light sensor.
